(19) United States
(12) Patent Application Publication
(10) Pub. No.: US 2016/0148863 A1
(43) Pub. Date: May 26, 2016

(54) NON-CONTIGUOUS DUMMY STRUCTURE SURROUNDING THROUGH-SUBSTRATE VIA NEAR INTEGRATED CIRCUIT WIRES

(71) Applicant: International Business Machines Corporation, Armonk, NY (US)

(72) Inventors: Fen Chen, Williston, VT (US); Mukta G. Farooq, Hopewell Junction, NY (US); John M. Safran, Wappingers Falls, NY (US)

(21) Appl. No.: 14/549,846

(22) Filed: Nov. 21, 2014

(51) Int. Cl. H01L 23/498; H01L 21/48

(52) U.S. Cl. CPC H01L 23/49827; H01L 23/49838; H01L 23/49811; H01L 23/498; H01L 21/4846; H01L 21/486; H01L 21/4885

(57) ABSTRACT

A three-dimensional (3-D) integrated circuit wiring including a plurality of stacked dielectric levels formed on a substrate includes a plurality of non-contiguous dummy walls patterned in a corresponding dielectric level around a circuit wire keep out zone (KOZ). The non-contiguous dummy walls are formed in the circuit wire KOZ and have an outer side and an opposing inner side that extend along a first direction to define a length. A circuit wire segment is located at a first metal level and a second circuit wire segment is located at a second metal level different from the first metal level. The first and second metal levels are located adjacent the inner side of at least one non-contiguous dummy wall.

### BACKGROUND

The present invention relates to multi-level wiring connecting semiconductor devices in an integrated circuit (IC), and more specifically, to stackable integrated circuits including through-substrate vias.

Through-substrate vias (TSVs) are implemented in a wide variety of multi-stack layered three-dimensional (3-D) integrated circuits, and provide vertical connections through one or more integrated circuit layers. Each layer consists of a substrate with circuit elements patterned therein, front end of line (FEOL) processing—and interconnect wiring constructed on the substrate surface—back end of line (BEOL) processing—that provides connections between the circuit elements. Referring to FIG. 1A, a top view of conventional multi-level wiring structure 100 adjacent to a TSV is illustrated. BEOL processing forms a plurality of conventional patterned metal layers 102 and 104 and interconnecting vias 106 in one or more dielectric layers 107 supported by a bulk substrate such as, for example, a bulk silicon substrate 103. A cross-sectional view of the conventional multi-level wiring structure 100 is illustrated in FIG. 1B. The first metal level 102 is located beneath the second metal level 104. The inter-level vias 106 connect one or more second metal level wires 104 and first metal level wires 102. After patterning the metal layers 102-104 and vias 106, a portion of one or more dielectric layers 107 within the circuit wiring keep out zone (KOZ) is etched vertically therethrough, and is then subsequently filled with a metallic material to form a metallic TSV 108 which extends through the multi-level wiring structure 100.

As the dielectric layers are formed (i.e., stacked) during the BEOL process, however, the patterning of the metal layers 102-104 and vias 106 can be distorted after TSV insertion. For example, an inner side of the dielectric layer adjacent to a region reserved for the TSV 108 can realize a metal pattern distortion effect. Consequently, the distorted metal patterning can compromise the reliability and performance of the 3-D integrated circuit wiring 100.

### SUMMARY

According to at least one embodiment of the present invention, a 3-D integrated circuit wiring including a plurality of stacked dielectric levels formed on a substrate includes a plurality of non-contiguous dummy walls patterned in a corresponding dielectric level around a circuit wire keep out zone (KOZ). The non-contiguous dummy walls are formed in the circuit wire KOZ and have an outer side and an opposing inner side that extend along a first direction to define a length. A circuit wire segment is located at a first metal level and a second circuit wire segment is located at a second metal level different from the first metal level. The first and second metal levels are located adjacent the inner side of at least one non-contiguous dummy wall.

According to another embodiment, a method of forming a 3-D integrated circuit wiring comprises stacking a plurality of dielectric levels on a substrate to define a thickness of the 3-D integrated circuit wiring. The method further includes performing a back end of line (BEOL) process to pattern a metal level and via in at least one of the dielectric levels. The method further includes patterning a plurality of non-contiguous dummy wall elements at a respective metal level. The method further includes forming a through-substrate via (TSV) in an associated circuit wire keep out zone (KOZ).

Additional features are realized through the techniques of the present invention. Other embodiments are described in detail herein and are considered a part of the claimed invention. For a better understanding of the invention with the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification.

The forgoing features are apparent from the following detailed description taken in conjunction with the accompanying drawings in which:

FIG. 1A is a top-down view illustrating a conventional 3-D integrated circuit wiring following a BEOL process to form a TSV through the 3-D integrated circuit layer and near a plurality of metal levels and vias;

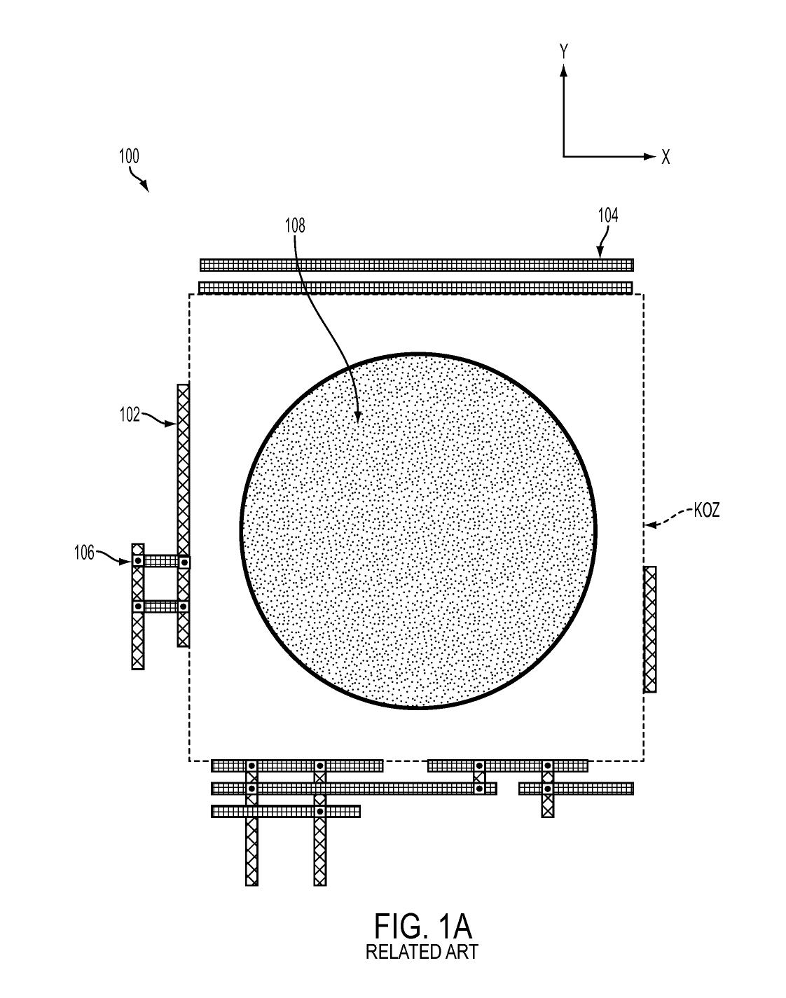

FIG. 1B is a cross-sectional view of the conventional 3-D integrated circuit wiring illustrated in FIG. 1A;

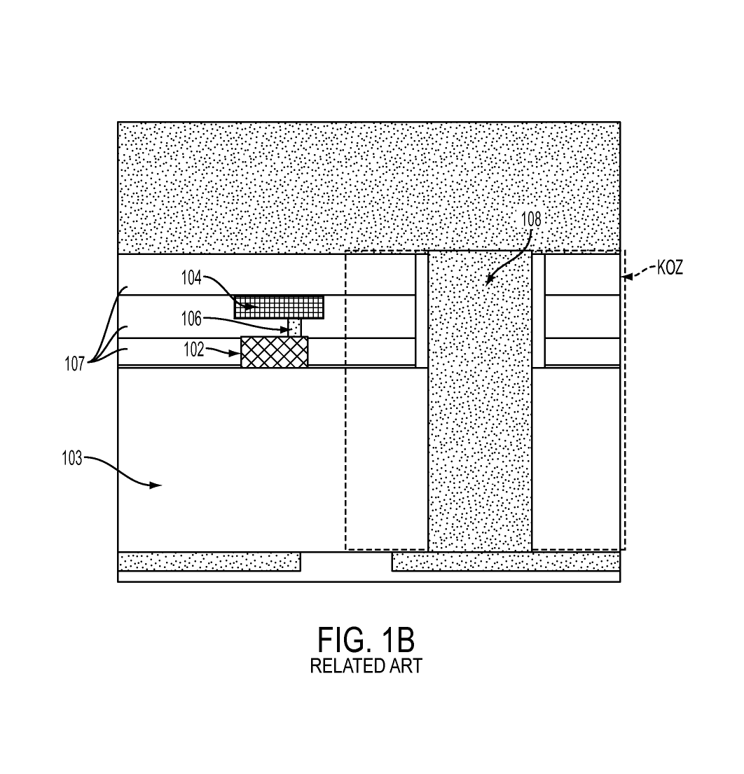

FIG. 2A is a top-down view illustrating a 3-D integrated circuit wiring following a patterning process to form a plurality of non-contiguous, dummy wall elements that isolate metal layers and via elements from a keep out zone (KOZ) according to a non-limiting embodiment of the disclosure;

FIG. 2B is a top-down view illustrating a 3-D integrated circuit wiring following a patterning process to form a plurality of non-contiguous, dummy wall elements that isolate metal layers and via elements separated from a keep out zone (KOZ) at a distance (d) according to a non-limiting embodiment of the disclosure;

FIG. 3 is a cross-sectional view of active metal layers and vias included in the 3-D integrated circuit wiring of FIG. 2A taken along line A-A according to a non-limiting embodiment;

FIG. 4 is a cross-sectional view of a portion of non-contiguous dummy wall elements included in the 3-D integrated circuit wiring of FIG. 2A taken along line B-B according to a non-limiting embodiment;

FIG. 5 is a top-down view illustrating the 3-D integrated circuit wiring shown in FIG. 2 after forming a TSV in the KOZ defined by the non-contiguous dummy wall elements according to a non-limiting embodiment of the disclosure;

FIG. 6 is a top-down view illustrating a 3-D integrated circuit wiring following a patterning process to form a plurality of non-contiguous dummy wall elements that isolate metal layers and via elements from a keep out zone (KOZ) according to a another non-limiting embodiment of the disclosure;

FIG. 7 is a top-down view illustrating a 3-D integrated circuit wiring following a patterning process to form a plurality of non-contiguous dummy wall elements that isolate metal layers and via elements from a keep out zone (KOZ) according to yet another non-limiting embodiment of the disclosure; and

FIG. 8 is a flow diagram illustrating a method of forming a 3-D integrated circuit wiring according to a non-limiting embodiment of the disclosure.

### DETAILED DESCRIPTION

Various embodiments of the disclosure provide a 3-D integrated circuit wiring that includes one or more non-contiguous dummy wall elements that maintain the patterning of active metal layers and/or via elements during the BEOL fabrication process. The non-contiguous dummy wall elements are patterned in each layer at the same time as the active metal layers and/or via elements. Therefore the non-contiguous dummy wall elements may be formed at each layer of the 3-D integrated circuit wiring.

The non-contiguous dummy wall elements themselves are also formed from metal according to well-known BEOL processes and isolate the active metal layers from a keep out zone (KOZ). The KOZ defines a region at which to etch one or more dielectric layers to form a void extending vertically therethrough. The void is then subsequently filled with a conductive material such as a metal material, for example, to form a through-substrate via (TSV). Unlike conventional 3-D integrated circuit wiring that use continuous dummy structures to protect the active metal regions from moisture and debris that may be introduced after the active metal layers are completely formed, the non-contiguous dummy wall elements of the present invention preserve the patterns of the active metal layers and vias layer by layer during BEOL fabrication process but without intruding any extra mechanical stress to the nearby vias. In this manner, the distortion effect of the active metal layers and interconnects is prevented, especially at the sides of the active metal layers supported by the non-contiguous dummy wall elements.

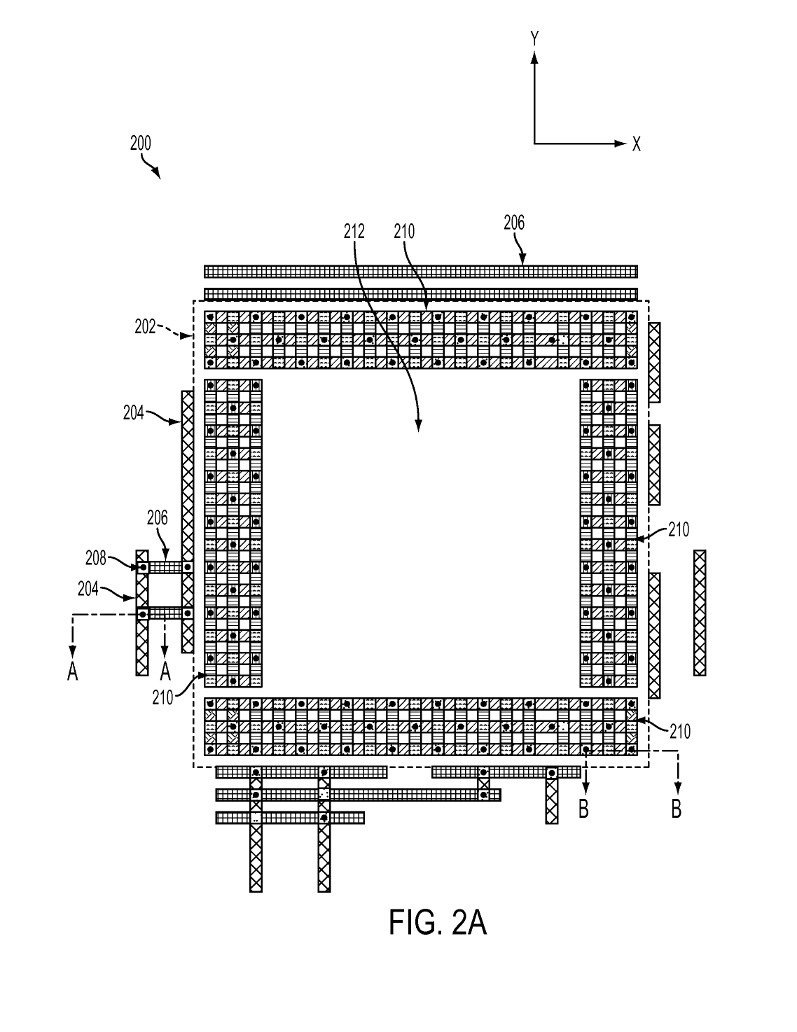

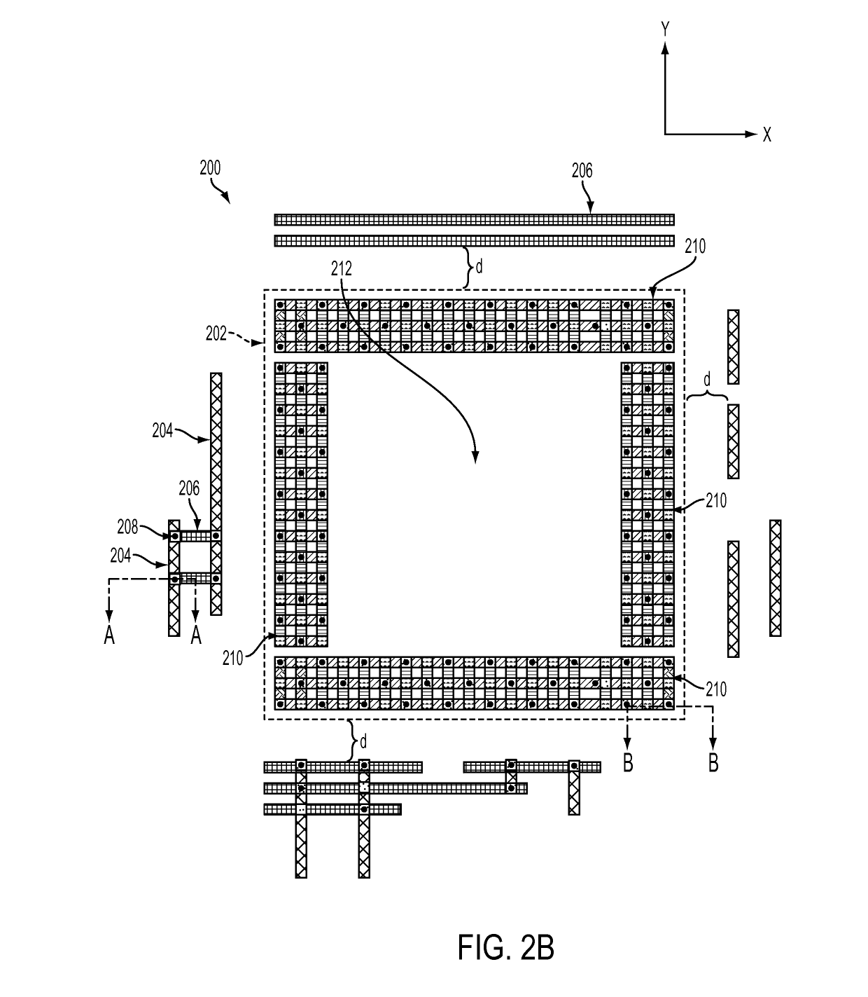

With reference now to FIG. 2, a top-down view of a 3-D integrated circuit wiring 200 is illustrated according to a non-limiting embodiment of the disclosure. The 3-D integrated circuit wiring 200 is shown following a patterning process to form a plurality of active metal layers 204-206, vias 208, and one or more non-contiguous dummy wall elements 210. It is appreciated that well-known BEOL processes may be used to form one or more dielectric layers 202 formed on a bulk substrate such as, for example, a bulk silicon substrate (not shown). Each dielectric layer 202 defines a dielectric level of the 3-D integrated circuit wiring 200.

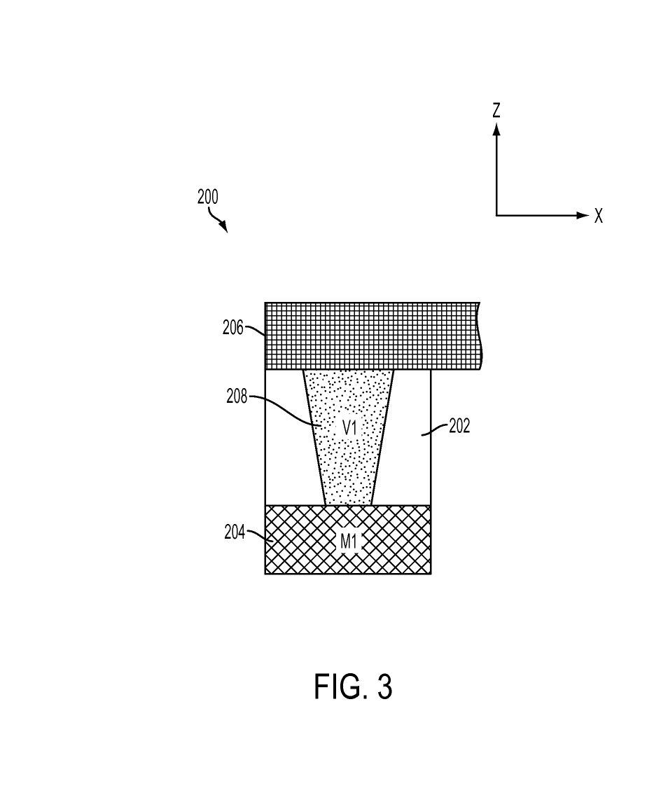

The active metal layers define metal levels of the 3-D integrated circuit wiring 200. The metal levels include a first active metal layer 204 and a second active metal layer 206 disposed at a different layer than the first metal layer 204. Each of the metal layers 204-206 may be configured as one or more integrated circuit wire segments. According to an embodiment, the first metal layer 204 is located beneath the second metal layer 206. It should be appreciated that a multitude of metal layers may be included beyond what is illustrated in FIG. 2. One or more vias 208 comprising an electrically conductive material (e.g., metal) connect the first active metal layer 204 to the second active metal layer 206 to establish electrical conductivity therebetween. Accordingly, one or more electrically conductive via elements 208 can be used to vertically connect (e.g., along the Z-axis) the second metal layer 206 to a first metal layer 204 (see FIG. 3).

The non-contiguous dummy wall elements 210 isolate the first metal layers 204, second metal layers 206, and via elements 208 from a dielectric KOZ 212. The dummy wall elements 210 extend along a first axis (e.g., X-axis) to define a length and a second axis (e.g., Y-axis) to define a width. Although FIG. 2A illustrates the integrated circuit wiring elements 204, 206 as being formed against the KOZ boundary 202, it is appreciated that one or more metal layers configured as integrated circuit wires, for example, can be spaced a distance (d) away from the dielectric layer 202 as illustrated in FIG. 2B.

As described above, the dummy wall elements 210 are patterned from a metal material at the same time the metal layers 204-206 and via elements 208 are formed during the BEOL process. Various metal etching techniques are used to form the walls including, but not limited to, reactive ion etching. Unlike conventional contiguous metal walls used to protect the active regions from moisture and debris, the dummy wall elements 210 are non-contiguously disposed in the KOZ 212. That is, each individual dummy wall element 210 is separated from another thereby rending the dummy wall elements 210 as non-contiguous walls. Such non-contiguous elements have a certain degree of freedom for structural expansion during various fabrication thermal cycles and after fabrication thermal cycles.

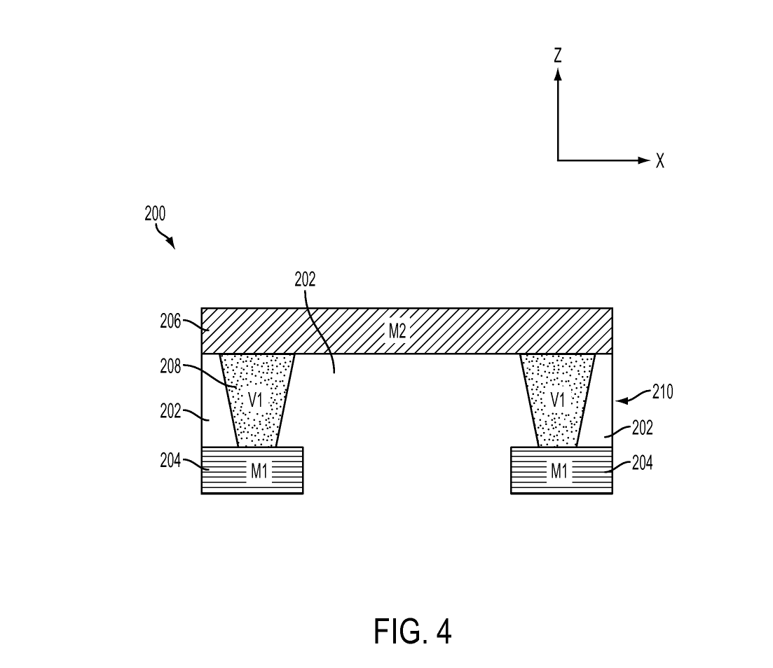

According to an embodiment, layers of the dummy wall elements 210 are included with each layer metal layer 204-206. In this manner, each dummy wall element 210 also extends along the thickness of the 3-D integrated circuit wiring 200, i.e., a Z-axis (see FIG. 4). In this manner, the dummy wall elements 210 isolate all active metal layers 204-206 and vias 210 from the KOZ 212. Accordingly, the pattern of the dummy walls 210 can be designed according to a particular application or design of the 3-D integrated circuit wiring 200.

Although four groups of dummy wall elements 210 are illustrated, it is appreciated that other embodiments of the invention may include less or more dummy wall elements 210. For example, if metal layers 204 -206 are formed on only two sides of the KOZ 212, then only two dummy wall elements 210 may be patterned as opposed to surrounding the entire KOZ 212 with a single continuous wall. Accordingly, materials and fabrication processing steps may be reduced.

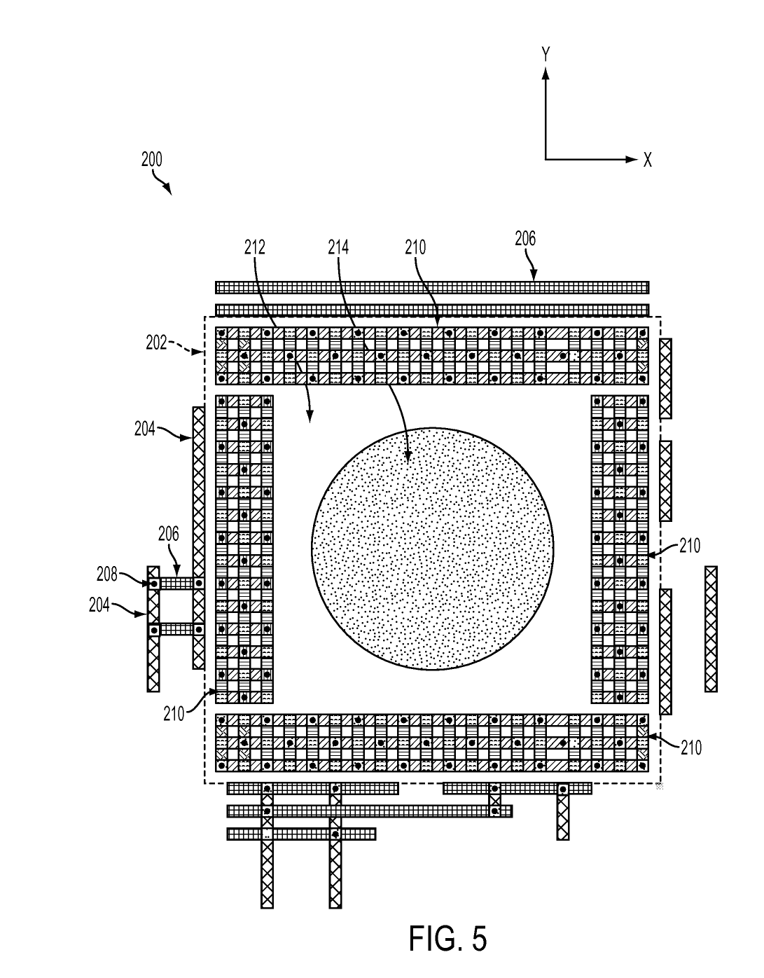

Turning now to FIG. 5, a TSV 214 is formed in the KOZ 212. The TSV 214 extends vertically, i.e., along a Z-axis (not shown in FIG. 5) and is formed according to well-known TSV formation processes. The TSV 214 comprises an electrically conductive metal material, for example, to provide a vertical electrical connection through the 3-D integrated circuit wiring 200 as understood by one of ordinary skill in the art. The dummy wall elements 210 isolate the first metal layers 204, second metal layers 206, and via elements 208 from the TSV 214 when forming the TSV 214. In this manner, the patterned metal layers 204 -206 and via elements 208 formed during a BEOL fabrication stage are further protected and maintained thereby improving the overall reliability and quality of the 3-D integrated circuit wiring 200.

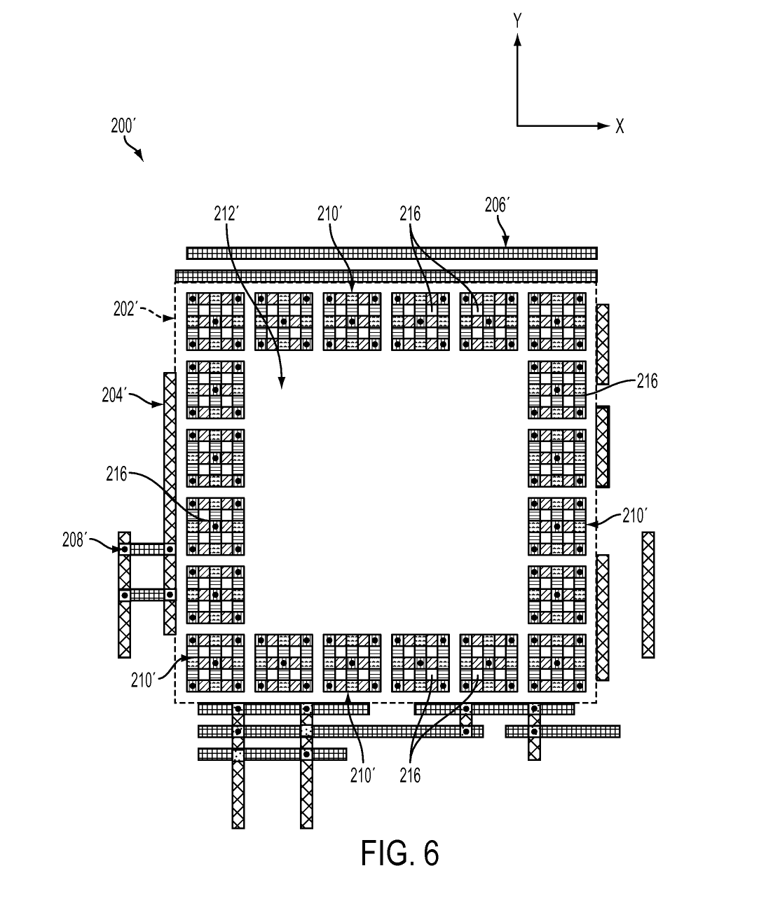

Turning to FIG. 6, a 3-D integrated circuit wiring 200′ is illustrated according to another embodiment of the disclosure. The 3-D integrated circuit wiring 200′ is shown following a patterning process to form a plurality of non-contiguous dummy wall elements 210′ that maintain the metal patterning during the BEOL fabrication process and isolate the active metal layers 204′-206′ and via elements 208′ from a KOZ 212′. The non-contiguous dummy wall elements 210′ are formed in a similar manner to the dummy wall elements 210 described with respect to FIGS. 2-4. Each dummy wall element 210′ of FIG. 6, however, comprises a plurality of individual wall units 216 that are separated and aligned with one another in the length direction (e.g., along the X-axis). Unlike a conventional continuous wall which experiences stress at the corners where each side of the wall meets, the inventive individual wall units 216 inhibit overall stress applied to each non-contiguous dummy wall 210′, thereby improving the overall reliability of the dummy walls 210′.

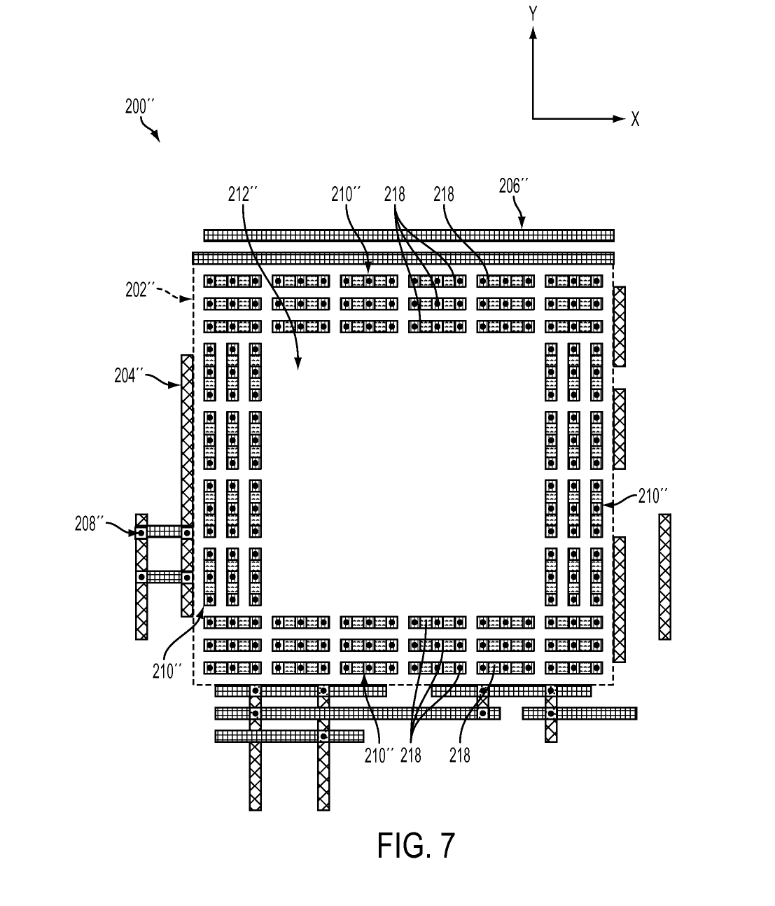

Turning to FIG. 7, a 3-D integrated circuit wiring 200″ is illustrated according to another embodiment of the disclosure. The 3-D integrated circuit wiring 200″ is shown following a patterning process to form a plurality of non-contiguous dummy wall elements 210 “ that isolate metal layers 204”-206″ and via elements 208″ from a KOZ 212″. The non-contiguous dummy wall elements 210″ are formed in a similar manner to the dummy wall elements 210 and 210′ described with respect to FIGS. 2-6. Each dummy wall element 210″ shown in FIG. 7, however, comprises a plurality of individual wall segments 218. The individual wall segments 218 are separated from one another along both the length direction (i.e., along the X-axis) and the width direction (i.e., along the Y-axis). In addition, the individual wall segments 218 can be aligned with one another in both the length direction (i.e., along the X-axis) and the width direction (i.e., along the Y-axis). In this manner, the individual wall segments 218 increase the precision at which the 204″-206″ and via elements 208″ are disposed with respect to KOZ 212″. In addition, the individual wall segments 218 further reduce the stress applied to the overall non-contiguous dummy wall elements 210″ since a single wall segment 218 is much smaller than a conventionally formed continuous wall.

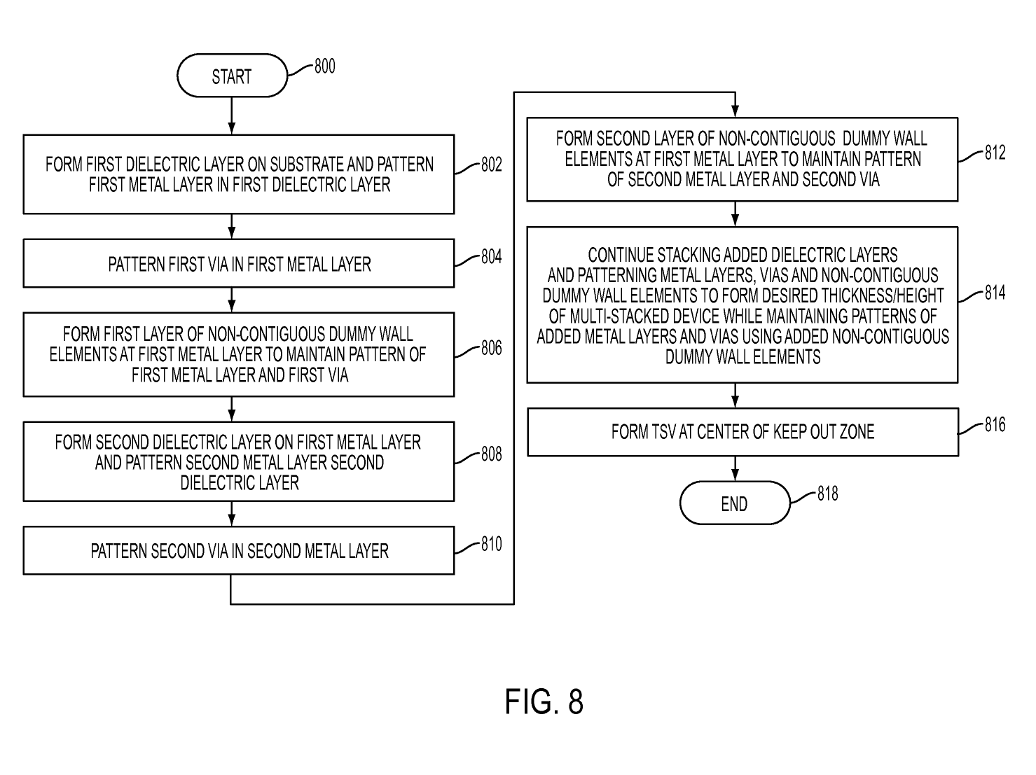

Turning now to FIG. 8, a flow diagram illustrates a method of forming a 3-D integrated circuit wiring according to a non-limiting embodiment of the disclosure. The method begins at operation 800, and at operation 802 a first dielectric layer is formed on a substrate and a first metal layer is formed, i.e., patterned, in the first dielectric layer. At operation 804, one or more first via layers are patterned in the first metal layer. At operation 806, a first layer of non-contiguous dummy wall elements are formed at the first metal layer. The first layer of non-contiguous dummy wall elements maintains the pattern of the first metal layer and the first interconnect elements. The combination of non-contiguous dummy wall elements defines a keep out zone of the dielectric layer that extends to the inner-sides of the non-contiguous dummy wall elements.

At operation 808, a second dielectric layer is formed on the first metal layer, and a second metal layer is patterned in the second dielectric layer. At operation 810, one or more second via elements are patterned in the second metal layer. At operation 812, a second layer of non-contiguous dummy wall elements are formed at the second metal layer. The second layer of non-contiguous dummy wall elements maintains the pattern of the second metal layer and the second vias. At operation 814, additional dielectric layers are stacked and patterned with metal layers, via elements, and non-contiguous dummy wall elements layer by layer as described above to form a desired thickness of the 3-D integrated circuit wiring. The non-contiguous dummy wall elements formed at each layer maintain the pattern of the metal layer and via elements as the 3-D integrated circuit wiring formed, e.g., stacked, during the BEOL process. At operation 816, an electrically conductive TSV is formed at the KOZ located adjacent the inner sides of the non-conductive dummy walls and is extended vertically through the 3-D integrated circuit wiring, and the method ends at operation 818. According to an embodiment, the TSV extends vertically through the thickness of the 3-D integrated circuit wiring and is formed adjacent to each non-contiguous dummy wall elements formed at each layer.

As described in detail above, various non-limiting embodiments of the invention include a 3-D integrated circuit wiring including non-contiguous dummy wall elements that preserve the patterns of the active metal layers and vias layer by layer during BEOL fabrication process. Further, the non-contiguous dummy wall elements that preserve the patterns of the active metal layers and vias layer without intruding any extra mechanical stress to the nearby vias. In this manner, the distortion effect of the active metal layers and interconnects is prevented, especially at the sides of the active metal layers supported by the non-contiguous dummy wall elements

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the inventive teachings and the practical application, and to enable others of ordinary skill in the art to understand the invention for various embodiments with various modifications as are suited to the particular use contemplated.

The flow diagrams depicted herein are just one example. There may be many variations to this diagram or the operations described therein without departing from the spirit of the invention. For instance, the operations may be performed in a differing order or operations may be added, deleted or modified. All of these variations are considered a part of the claimed invention.

While various embodiments have been described, it will be understood that those skilled in the art, both now and in the future, may make various modifications which fall within the scope of the claims which follow. These claims should be construed to maintain the proper protection for the invention first described.

What is claimed is:

1. A three-dimensional (3-D) integrated circuit wiring including a plurality of stacked dielectric levels formed on a substrate, the 3-D integrated circuit wiring comprising:
a plurality of metal levels patterned in respective dielectric layers, each dielectric layer defining a dielectric level of the 3-D integrated circuit wiring;
a plurality of circuit vias patterned to connect at least one first metal level in a respective dielectric level to at least one second metal level in a different respective dielectric level;
a circuit wire keep out zone (KOZ) associated with the TSV; and
a plurality of non-contiguous dummy wall elements patterned in a corresponding dielectric level within a circuit wire keep out zone defined in the three-dimensional (3-D) integrated circuit wiring.

2. The 3-D integrated circuit wiring of claim 1, further comprising at least one through-substrate via (TSV) formed in the circuit wire KOZ, the at least one TSV extending vertically through the substrate and the plurality of dielectric levels.

3. The 3-D integrated circuit wiring of claim 2, wherein the at least one TSV extends vertically through the 3-D integrated circuit wiring at a first vertical distance, and wherein the non-contiguous dummy wall elements extend vertically through the 3-D integrated circuit wiring at a second vertical distance, and wherein the second vertical distance is at least one dielectric level less than the first vertical distance.

4. The 3-D integrated circuit wiring of claim 3, further comprising at least one via element that electrically connects a first metal level to the second metal level.

5. The 3-D integrated circuit wiring of claim 4, wherein each non-contiguous dummy wall element includes a plurality of individual wall units that are separated from one another.

6. The 3-D integrated circuit wiring of claim 5, wherein the individual dummy wall units are aligned with one another along a first direction.

7. The 3-D integrated circuit wiring of claim 4, wherein each non-contiguous dummy wall element includes a plurality of individual wall segments that are separated from one another along the first direction and a second direction opposite the first direction.

8. The 3-D integrated circuit wiring of claim 7, wherein the individual dummy wall segments are aligned with one another along the first direction and along the second direction.

9. The 3-D integrated circuit wiring of claim 4, wherein at least one integrated circuit wire is spaced away from the outer sides of the circuit wire KOZ.

10. The 3-D integrated circuit wiring of claim 4, wherein the circuit wires are abutting the outer sides of the circuit wire KOZ.

11. A method of forming a 3-D integrated circuit wiring, the method comprising:
stacking a plurality of dielectric levels on a substrate to define a thickness of the 3-D integrated circuit wiring;
performing a back end of line (BEOL) process to pattern a metal level and via in at least one of the dielectric levels;
patterning a plurality of non-contiguous dummy wall elements at a respective metal level;
and forming a through-substrate via (TSV) in an associated circuit wire keep out zone (KOZ).

12. The method of claim 11, further comprising forming a through-substrate via (TSV) vertically through the 3-D integrated circuit wiring while protecting integrated circuit wires of a respective metal level using the non-contiguous dummy wall elements.

13. The method of claim 12, further comprising extending the non-contiguous dummy wall elements vertically through the 3-D integrated circuit wiring at a first vertical distance, and further extending the TSV vertically through the 3-D integrated circuit wiring a second vertical distance wherein the second vertical distance is at least one dielectric level greater than the first vertical distance.

14. The method of claim 13, further comprising electrically connecting a first metal level to a second metal level.

15. The method of claim 14, wherein each non-contiguous dummy wall element includes a plurality of individual wall units that are separated from one another.

16. The method of claim 15, further comprising aligning the individual wall units along the first direction.

17. The method of 14, wherein each non-contiguous dummy wall element includes a plurality of individual wall segments that are separated from one another along the first direction and a second direction opposite the first direction.

18. The method of claim 17, further comprising aligning the individual wall segments along the first direction and along a second direction perpendicular to the first direction.

19. The method of claim 14, further comprising spacing the first and second integrated circuit wires a distance away from the outer sides of the circuit wire keep out zone (KOZ).

20. The method of claim 14, further comprising abutting the at least one integrated circuit wire to the outer sides of the circuit wire keep out zone (KOZ).
